(19) United States
(12) Patent Application Publication
(10) Pub. No.: US 2025/0291979 A1
(43) Pub. Date: Sep. 18, 2025

(54) GENERATING DIGITAL TWINS

(71) Applicant: Schlumberger Technology Corporation, Sugar Land, TX (US)

(72) Inventors: Lante Carbognani, Calgary (CA); Steven Smith, Calgary (CA); Ghazala Fazil, Calgary (CA); Richard Booth, Houston, TX (US)

(21) Appl. No.: 18/885,187

(22) Filed: Sep. 13, 2024

Related U.S. Application Data
(60) Provisional application No. 63/593,836, filed on Oct. 27, 2023.
(60) Provisional application No. 63/564,581, filed on Mar. 13, 2024.

(51) Int. Cl. G06F 30/27

(52) U.S. Cl. CPC G06F 30/27

(57) ABSTRACT

A digital twin generator may receive a model for the physical asset, the model including one or more bound parameters and one or more static parameters associated with the model. A digital twin generator may bind the one or more bound parameters to historical sensor data from a sensor at the physical asset. A digital twin generator may receive a physical measurement from the sensor at the physical asset, the physical measurement including an update to the historical sensor data. A digital twin generator may generate an updated model including the one or more updated bound parameters and the one or more static parameters.

### RELATED APPLICATION

This application claims priority to and the benefit of a U.S. Provisional Application having Ser. No. 63/564,581, filed Mar. 13, 2024, which is incorporated by reference herein in its entirety.

### BACKGROUND OF THE DISCLOSURE

A digital twin is a digital representation of a real system, with the aim to fully digitally simulate the real system. Conventionally, digital twin creation is a complex process that utilizes one or more models, including but not limited to simulation, surrogates, ML/AI, hybrids. Typically, this involves consolidating and listing available sources of information, creating orchestrators, designing, and implementing visualization, managing models, and ingesting data and configuring data binding. Such tasks are time-consuming, resulting bespoke solutions that are difficult to adapt and scale to other situations, including small changes to a particular situation.

### SUMMARY

In some aspects, the techniques described herein relate to a method for generating an evergreen digital twin of a physical asset. A digital twin generator receives a model for the physical asset. The model includes one or more bound parameters and one or more static parameters associated with the model. The digital twin generator binds the one or more bound parameters to historical sensor data from a sensor at the physical asset. The digital twin generator receives a physical measurement from the sensor at the physical asset. The physical measurement includes an update to the historical sensor data. The digital twin generator generates an updated model including the one or more updated bound parameters and the one or more static parameters.

In some aspects, the techniques described herein relate to a method for implementing a digital twin. A service orchestrator receives a request to perform a service using the digital twin. The digital twin is representative of a physical asset. Based on the service, the service orchestrator adjusts at least one bound parameter of the digital twin. The at least one bound parameter is associated with an operating parameter or operating state of the physical asset. The service orchestrator performs the service with the digital twin to generate an output. The output is representative of a change in the physical asset based on the at least one bound parameter.

In some aspects, the techniques described herein relate to a system, including: a processor and memory, the memory including instructions that cause the processor to: receive a model for a physical asset, the model including one or more bound parameters and one or more static parameters associated with the model; bind the one or more bound parameters to historical sensor data from a sensor at the physical asset; receive a physical measurement from the sensor at the physical asset, the physical measurement including an update to the historical sensor data; and generate an updated model including the one or more updated bound parameters and the one or more static parameters.

This summary is provided to introduce a selection of concepts that are further described in the detailed description. This summary is not intended to identify key or essential features of the claimed subject matter, nor is it intended to be used as an aid in limiting the scope of the claimed subject matter. Additional features and aspects of embodiments of the disclosure will be set forth herein, and in part will be obvious from the description, or may be learned by the practice of such embodiments.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a schematic representation of a digital twin generation system, according to at least one embodiment of the present disclosure.

FIG. 2 is a representation of a digital twin manager, according to at least one embodiment of the present disclosure.

FIG. 3 is a string diagram of the generation of an evergreen digital twin, according to at least one embodiment of the present disclosure.

FIG. 4 is a string diagram of the generation of an evergreen digital twin, according to at least one embodiment of the present disclosure.

FIG. 5 is a schematic illustration of a digital twin generator, according to at least one embodiment of the present disclosure.

FIG. 6 is a representation of a GUI of a digital twin generator, according to a least one embodiment of the present disclosure.

FIG. 7-1 and FIG. 7-2 are representations of a GUI of a digital twin generator, according to at least one embodiment of the present disclosure.

FIG. 8 is a flowchart of a method for generating a digital twin, according to at least one embodiment of the present disclosure.

FIG. 9 is a flowchart of a method for implementing a service on a digital twin, according to at least one embodiment of the present disclosure.

FIG. 10 is a representation of a computing system, according to at least one embodiment of the present disclosure.

### DETAILED DESCRIPTION

This disclosure generally relates to devices, systems, and methods for a widely applicable and scaleable digital twin generator. The digital twin generator may generate digital twins of physical facilities or assets. For example, the digital twin generator may generate digital twins of oil and gas processing systems, drilling operation systems, manufacturing system, operational systems, any other systems, and combinations thereof. Conventionally, digital twins were generated by hand, using specialized programming, application program interfaces (APIs), software versions, models, and other elements. Such digital twins are difficult to reproduce, resulting in specialized digital twins that are representative of a particular instance of a particular physical facility or asset.

In accordance with at least one embodiment of the present disclosure, a digital twin generator may generate an evergreen digital twin that is maintained based on sensor data from one or more sensors at the physical asset. When a digital twin is generated, the digital twin may include a stable version of a model and/or combination of models that has been customized to represent a particular physical asset. The model may include multiple parameters that are utilized to output a simulated result of the physical asset. Adjusting the model to be representative of the physical asset may include an adjustment to the various parameters. A stable model may be generated when the relationships between parameters and values of particular parameters outputs a simulated result representative of the actual status of the physical asset, and changes to parameters represent the associated changes to the physical asset and its associated status.

A digital twin is generated when physical measurements collected from the field are input into the stable model and the output from the stable model is representative of the state of the physical system. Conventionally, digital twins are representative of a single instance of the physical asset based on a single set of physical measurements. In accordance with at least one embodiment of the present disclosure, the digital twin generator may bind certain bound parameters of the model to physical measurements of the physical asset.

When the digital twin generator receives new physical measurements, the bound parameters may be updated with the new physical measurements. This may cause the digital twin to be updated to the state of the physical asset at the time of the physical measurements. The models may be periodically or episodically updated to generate an evergreen digital twin, or a digital twin that is maintained up to date based on measurements from the physical asset.

In accordance with at least one embodiment of the present disclosure, the evergreen digital twin may be used to perform various analyses and simulations of the physical asset. For example, a service orchestrator may adjust one or more of the parameters of the underlying models in the digital twin. The results of the simulation may then be used to identify how changes in the parameters of the physical asset impact the operation of the physical asset. The service orchestrator may implement multiple types of services, such as optimization analyses, what-if scenarios, case studies, forecasting, and so forth. In this manner, the service orchestrator may identify how changes to the operating parameters of the physical system may impact the operation of the physical system without adjusting the system itself.

The evergreen digital twin system provides many advantages and benefits over conventional systems and methods. For example, by binding certain parameters of the digital twin to physical measurements, the evergreen digital twin system improves the relevance and/or accuracy of digital twins. Such improvements over conventional modeling techniques facilitate continued use of the digital twin based on updating the stable underlying models.

Further, by maintaining the evergreen digital twin, the evergreen digital twin system may perform analyses and other simulations based on an up-to-date instance of the digital twin. In this manner, the evergreen digital twin system may identify how changes to the physical asset may impact operation of the physical asset. This may improve operating efficiency, improve production, or otherwise improve operation of the physical asset.

As illustrated by the foregoing discussion, the present disclosure utilizes a variety of terms to describe features and advantages of the evergreen digital twin system. Additional detail is now provided regarding the meaning of such terms. For example, as used herein, the term “digital twin” refers to a digital representation of a physical asset. In particular, the term “digital twin” can include a digital representation of one or more elements of a physical asset, such as a process, a device or piece of equipment, flow of material through the physical asset, the physical arrangement of the physical asset, and so forth. To illustrate, a digital twin may include one or more models, simulations, or other digital representations of the physical asset.

The digital twin may generate one or more outputs. The outputs of the digital twin may be based on the elements the physical asset, including, but not limited to, resource consumption (e.g., electricity, fuel, materials) quantity and/or rate, resource generation (e.g., oil, gas) quantity and/or rate, waste generation (e.g., carbon dioxide, cuttings) quantity and/or rate, cost, profit, equipment wear and tear, any other output, and combinations thereof. The digital twin may include various parameters (and various relationships between the parameters) that generate the digital representation of the physical asset. Adjusting the parameters of the digital twin may result in changes to the output of the digital twin. As discussed in further detail herein, one or more of the parameters may be bound to a measurable input parameter or operating parameter that an operator may change to change the output of the physical asset. In accordance with at least one embodiment of the present disclosure, an evergreen digital twin may be a digital twin that is maintained up-to-date based on physical measurements measured by a sensor at the associated physical asset.

As used herein, a “physical asset” is a real-world element that has one or more measurable or quantifiable properties. For example, a physical asset may include facilities, such as production and processing equipment, storage and offloading equipment, power and utilities, drilling and well equipment, control and monitoring equipment, structural and mechanical equipment. In some examples, a physical asset may include pipeline assets, such as main pipeline equipment, compression and pumping equipment, monitoring and control equipment, safety and environmental protection equipment, structural and mechanical equipment, electrical and power equipment, communication and navigation systems, maintenance and inspection equipment, ancillary equipment. In some examples, a physical asset may include other equipment, such as a physical facility, unit of equipment, equipment set, tool, structure, process, fluid flow path, any other physical element, and combinations thereof.

As discussed above, physical assets may include facilities. As a non-limiting example, production and processing equipment may include oil separation units, gas compressors, water treatment units, dehydration units, desalters, heat exchangers, reboilers, heaters, coolers, flare systems, chemical injection systems, gas-lift systems, any other production and processing equipment, and combinations thereof. As a non-limiting example, storage and offloading equipment may include cargo tanks, ballast system, offloading hoses and buoys, mooring systems, loading arms, crude oil pumps, any other storage and offloading equipment, and combinations thereof. As a non-limiting example, power and utilities may include power generation units, fuel gas systems, water makers, HVAC systems, compressed air systems, emergency power systems, steam boilers, fire and gas detection systems, any other power and utilities, and combinations thereof. As a non-limiting example, safety and environmental systems may include firefighting systems, life-saving equipment, gas detection systems, emergency shutdown systems (ESD), oil spill response equipment, inert gas systems, any other safety and environmental systems, and combinations thereof. As a non-limiting example, drilling and well equipment may include wellhead control systems, subsea equipment, riser towers, any other drilling and well equipment, and combinations thereof. As a non-limiting example, control and monitoring systems may include distributed control systems (DCS), supervisory control and data acquisition (SCADA), instrumentation, navigation systems, any other control and monitoring systems, and combinations thereof. As a non-limiting example, structural and mechanical equipment may include topsides modules, hull and deck structures, cranes and lifting equipment, piping systems, structural supports and skids, any other structural and mechanical equipment, and combinations thereof.

As discussed above, physical assets may include pipeline assets. As a non-limiting example, main pipeline equipment may include pipes, valves, flanges and fittings, gaskets, pigs and pigging stations, pipeline coatings, any other main pipeline equipment, and combinations thereof. As a non-limiting example, compression and pumping equipment may include compressors, pumps, pump stations, metering stations, surge vessels, any other compression and pumping equipment, and combinations thereof. As a non-limiting example, monitoring and control systems may include supervisory control and data acquisition (SCADA), flow meters, pressure transmitters, temperature sensors, leak detection systems, control valves, remote terminal units (RTUs), any other monitoring and control systems, and combinations thereof. As a non-limiting example, safety and environmental protection equipment may include emergency shutdown systems (ESD), block valve stations, pressure relief valves, fire and gas detection systems, cathodic protection systems, pig traps, any other safety and environmental protection equipment, and combinations thereof. As a non-limiting example, structural and mechanical equipment may include supports and anchors, expansion loops and joints, scraper traps, hot tapping equipment, isolation joints, any other structural and mechanical equipment, and combinations thereof. As a non-limiting example, electrical and power systems may include power generators, battery backup systems, uninterruptible power supply (UPS), any other electrical and power systems, and combinations thereof. As a non-limiting example, communication and navigation systems may include fiber optic cables, radio and satellite communication, GPS and geographical information systems (GIS), any other communication and navigation systems, and combinations thereof. As a non-limiting example, maintenance and inspection equipment may include in-line inspection tools (smart pigs), hypostatic testing equipment, ultrasonic testing tools, magnetic flux leakage (MFL) tools, any other maintenance and inspection equipment, and combinations thereof. As a non-limiting example, ancillary equipment may include sump tanks, pigging accessories, pig signalers, any other ancillary equipment, and combinations thereof.

As discussed herein, physical assets may include other equipment. As a non-limiting example, a physical facility may include a power plant, an oil and gas refinery, a drilling system, a wellsite intervention system, an oil and gas production system, a pipeline, a pumping system, any other physical facility, and combinations thereof. As a non-limiting example, a unit of equipment may include a drill rig, a downhole tool, a unit of mobile equipment (e.g., pickup truck, haul truck, loader, forklift, crane, truck-mounted drill), a motor, a compressor, a pump, a sensor, a bit, a downhole tool, any other equipment, and combinations thereof. As a non-limiting example, an equipment set may include a combination of equipment configured to perform a particular task, such as a bottom hole assembly (BHA), a drill rig, oil and gas processing equipment, an injection system, any other equipment set, and combinations thereof. As a non-limiting example, a tool may include any tool, such as hand tools, powered tools, electric tools, hydraulic tools, pneumatic tools, downhole drilling tools, downhole production tools, surface construction tools, surface production tools, any other tool, and combinations thereof. As a non-limiting example, a structure may include any structure, such as a tank, a pit, a steel structure, a concrete structure, piping, a building, any other structure, and combinations thereof. As a non-limiting example, a fluid flow path may include any fluid flow path and the associated piping, valves, and pumps, such as a drilling fluid flow path, an oil and gas production fluid flow path, coolant fluid flow, gas fluid flow paths, any other fluid flow paths, and combinations thereof.

As used herein, a static parameter may be a parameter of a digital twin (or a model or process underlying the digital twin) that is not changed during updating of the digital twin. For example, a static parameter may include one or more variables, constants, connections, or other element of a model or process that maintains stable operation of the digital twin.

As used herein, a bound parameter may be a parameter of a digital twin (or a model or process underlying the digital twin) that is changed during updating of the digital twin. For example, the bound parameters may be bound to one or more sensor measurements. In some examples, the bound parameters may be bound to an input value, such as an operating state of a unit of equipment. Changing the bound parameters may result in a change in the output of the digital twin. In some embodiments, changing the bound parameters may not change the static parameters, or may not change the stability of the digital twin based on the interplay between the static parameters and the bound parameters.

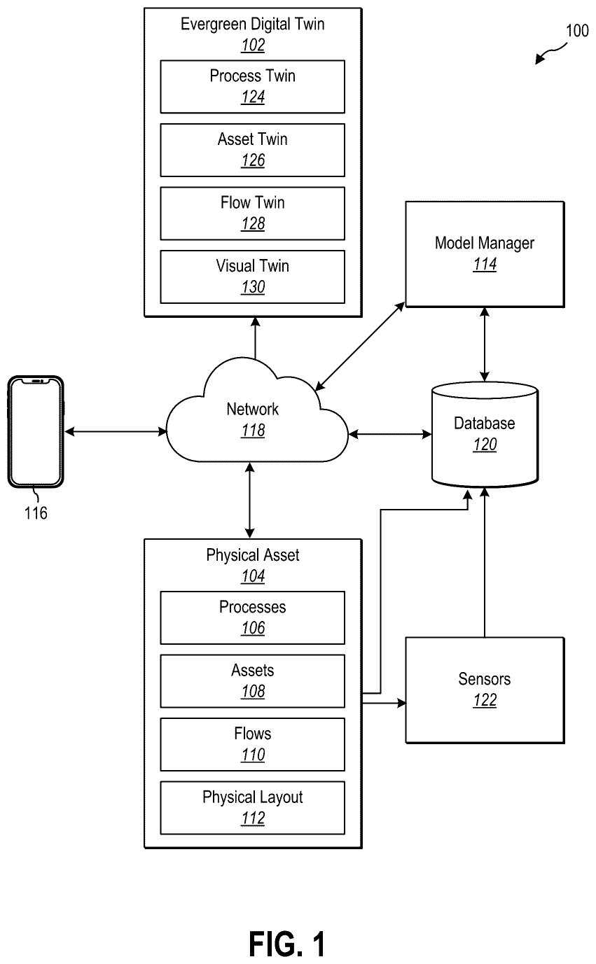

FIG. 1 is a schematic representation of a digital twin generation system 100, according to at least one embodiment of the present disclosure. The digital twin generation system 100 may generate one or more evergreen digital twins 102 that are digital representations of a physical asset 104. As discussed herein, the physical asset 104 may be any type of physical asset, including a process 106, equipment 108, flows 110, a physical layout 112, any other physical asset 104, and combinations thereof.

The digital twin generation system 100 may include a model manager 114. The model manager 114 may include one or more models, simulations, or other element that may contribute to the formation of a digital twin. For example, the model manager 114 may include one or more physics models, surrogate models, hybrid models, data models, flow assurance models, drilling models, geological models, visualization models, three-dimensional rendering models, simulations, steady-state simulation models, dynamic simulation models, any other model or simulation, and combinations thereof.

A user may, via a user device 116 in communication with the model manager 114 over a network 118 (such as a local network and/or the Internet), request a digital twin, or a simulation or service from a digital twin. A digital twin manager may receive one or more models from the model manager 114 to form the evergreen digital twin 102. For example, the digital twin manager may, based on the request received at the user device 116, identify what type of digital twin to generate, the scope of the digital twin, and the underlying models and/or simulations that may be used to generate the digital twin.

The model manager 114 may maintain the models based on sensor data stored within a database 120. For example, one or more sensors 122 may collect or measure physical measurements from the elements of the physical asset 104. The sensors 122 may store the historical sensor data in the database 120. The model manager 114 may include a stable version of the various models. The digital twin may be generated at a particular instance in time based on the physical measurements collected from the sensors 122.

When the user requests a digital twin through the user device 116, the digital twin generation system 100 may select the models or simulations from the model manager 114 and update the models with up-to-date sensor data from the sensors 122. Updating the digital twin may result in an evergreen digital twin 102, or a digital twin that is maintained in a state that is representative of real-world conditions of the physical asset 104.

The evergreen digital twins 102 may be any type of digital twin. For example, the evergreen digital twins 102 may include a process twin 124, an asset twin 126, a flow twin 128, a visual twin 130, any other digital twin, and combinations thereof. A process twin 124 may be a digital twin that is a digital representation of a physical process. For example, a process twin 124 may be a digital representation of a drilling system, an entire processing plant, a manufacturing facility, a warehouse, any other physical process, and combinations thereof. The process twin 124 may include various elements, including different units of equipment, structures, personnel, materials, and so forth. The process twin 124 may further include interactions between the elements of the physical process. As a specific, non-limiting example, a process twin 124 may include a drilling system, and the process twin 124 may include an interaction between hookload of the topdrive, the length of the drill string, the rate of rotation of the drill string, the geometry of the wellbore, and the resulting forces (e.g., weight-on-bit and torque) applied to the drill string and associated tools.

An asset twin 126 may include a digital representation of a particular physical asset, such as a unit of equipment. The asset twin 126 may include a data model or a data-driven model of the physical asset. The asset twin 126 may identify performance parameters of the asset. In some embodiments, the asset represented by the asset twin 126 may be included as part of the physical process represented by the process twin 124. The asset twin 126 may provide a data-driven model of the operation of the asset, including the impact on operating efficiency, operating lifetime, and maintenance schedules. The process twin 124 may identify how the inputs and outputs of the asset represented by the asset twin 126 impact the overall operation of the physical process.

A flow twin 128 may include a digital representation of a flow of materials through a system. For example, the flow twin 128 may be the representation of a fluid flow of a fluid through the system, such as a drilling fluid, an oil and gas production flow, a refinery flow of fluid through a refinery, and so forth. The flow twin 128 may include fluid dynamic models or other models and simulations that estimate the behavior of the fluid in a system.

A visual twin 130 may include a visual, 2-dimensional or 3-dimensional, representation of a physical asset. The visual twin 130 may be generated using physical surveys to identify the spatial relationships between elements or portions of the physical asset. The visual twin 130 may identify changes in the physical structure of the physical asset. This may help to identify changes in structural integrity and/or stability of certain elements.

As may be seen, the digital twins may utilize some of the same information and/or provide some of the same analysis of the physical asset. For example, a process twin 124 may include a pumping system, the asset twin 126 may include a pump used in the pumping system, the flow twin 128 may model the flow of fluid through the pumping system, and the visual twin 130 may identify the spatial layout of pumping elements, such as piping, pumps, valves, and so forth. In some embodiments, the digital twins may communicate with each other to provide the relevant inputs and outputs based on the modeled elements.

The underlying models used to build the digital twins may be stable versions of the models. For example, when a new project is started, an operator or engineer may customize existing models based on the specific details of the system. The customized models may be tested based on measurements from the sensors 122, as stored in the database 120. The model manager 114 may maintain the stable and up-to-date versions of the models on the cloud, and may limit access to prior versions from the user.

To generate the digital twin, the digital twin generation system 100 may bind certain bound parameters in the models to sensor measurements and other inputs. For example, the bound parameters may be tied to the output of sensors and/or equipment settings. Binding the bound parameters to sensor measurements and/or equipment settings may facilitate easy updating of the models used to generate the digital twin. When the sensors 122 measure new measurements and/or the equipment settings changed, the bound parameters may be updated. This may result in the evergreen digital twins 102, or the digital twins that are representative of the most recently measured state of the physical asset. In this manner, by maintaining stable versions of the models and regularly updating the bound parameters, the evergreen digital twins 102 may be representative of actual conditions of the physical asset.

In accordance with at least one embodiment of the present disclosure, the digital twin generation system 100 may prepare one or more simulations of the physical asset 104 to simulate the impact of various changes to the physical asset 104. For example, and as discussed in further detail herein, the digital twin generation system 100 may adjust one or more of the bound parameters and identify the simulated impact on the physical asset 104. In this manner, the user may identify how changes to the physical asset 104 may impact operation of the physical asset 104 without having to physically make changes to the physical asset 104. In some embodiments, after identifying the simulated impact of the changes to the physical asset 104, the digital twin generation system 100 may implement the change to the physical asset 104.

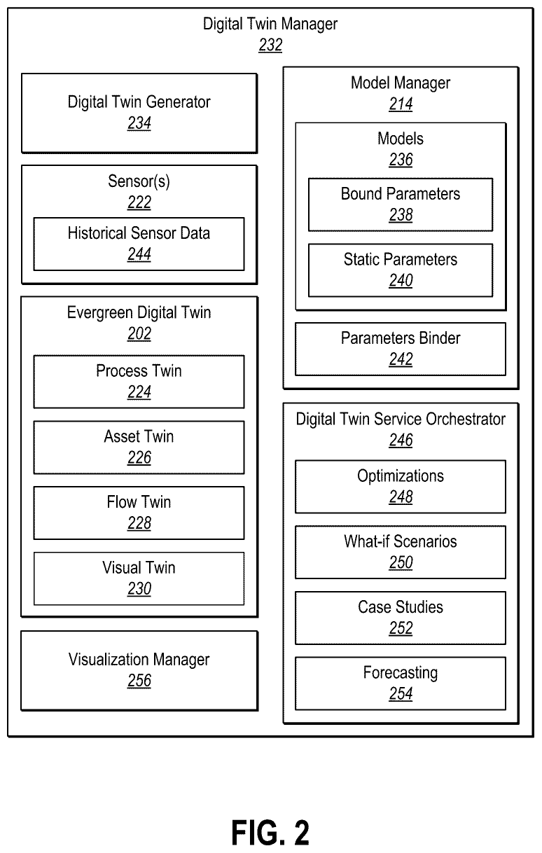

FIG. 2 is a representation of a digital twin manager 232, according to at least one embodiment of the present disclosure. Each of the components of the digital twin manager 232 can include software, hardware, or both. For example, the components can include one or more instructions stored on a computer-readable storage medium and executable by processors of one or more computing devices, such as a client device or server device. When executed by the one or more processors, the computer-executable instructions of the digital twin manager 232 can cause the computing device(s) to perform the methods described herein. Alternatively, the components can include hardware, such as a special-purpose processing device to perform a certain function or group of functions. Alternatively, the components of the digital twin manager 232 can include a combination of computer-executable instructions and hardware.

Furthermore, the components of the digital twin manager 232 may, for example, be implemented as one or more operating systems, as one or more stand-alone applications, as one or more modules of an application, as one or more plug-ins, as one or more library functions or functions that may be called by other applications, and/or as a cloud-computing model. Thus, the components may be implemented as a stand-alone application, such as a desktop or mobile application. Furthermore, the components may be implemented as one or more web-based applications hosted on a remote server. The components may also be implemented in a suite of mobile device applications or “apps.”

The digital twin manager 232 may include a digital twin generator 234. The digital twin generator 234 may receive an input from a user requesting a digital twin, or an update to an existing digital twin. When the digital twin generator 234 receives the input from the user, the digital twin generator 234 may identify one or more models 236 from the model manager 214. For example, the digital twin generator 234 may identify which of the models 236 are relevant to the digital twin. In some examples, the digital twin generator 234 may identify which of the models 236 are used by the digital twin to be updated.

As discussed herein, the models 236 may include one or more bound parameters 238 and one or more static parameters 240. The models 236 may be stable models. The stability of the models may be at least partially based on the static parameters 240 that may not change, or may not be changeable by the user. The bound parameters 238 may be changeable by the user. For example, a parameters binder 242 may bind the bound parameters 238 to sensor output from sensors 222 and/or an operating status of one or more elements of the physical asset.

The parameters binder 242 may bind the bound parameters 238 to physical measurements and/or the operating status in any manner. For example, the parameters binder 242 may include input from an operator or engineer that develops the models 236. In some examples, the parameters binder 242 may identify correlations between physical measurements and operating status using one or more machine learning models and/or artificial intelligence models. As discussed herein, the model manager 214 may maintain stable instances of the models 236 based on historical sensor data 244 from the sensors 222 and associated operating status.

The sensors 222 may include any type of sensor associated with the physical asset. For example, the sensors 222 may include sensors on an Internet of Things (IoT) device. In some examples, the sensors 222 may include a temperature sensor (including thermocouples, resistance temperature detectors (RTDs), thermistors, infrared sensors, bimetallic sensors), a pressure sensor (including strain gauge pressure sensors, piezoelectric pressure sensors, differential pressure sensors, absolute pressure sensors, gauge pressure sensors), a flow rate sensor (including turbine flow meters, ultrasonic flow meters, Coriolis flow meters, magnetic flow meters, vortex flow meters, orifice plate sensors), a vibration sensor (including accelerometers, piezoelectric vibration sensors, proximity probes), a torque sensor, a rotational rate sensor, a gyroscope, RADAR, LIDAR, ground penetrating radar (GPR), level sensors (including float level sensors, ultrasonic level sensors, radar level sensors, conductive level sensors, optical level sensors), current and voltage sensors (current transformers, hall effect sensors, voltage sensors), gas and chemical sensors (including catalytic bead sensors, electrochemical sensors, infrared gas sensors, photoionization detectors (PID), metal oxide semiconductor (MOS) sensors, flame ionization detectors (FID)), humidity sensors (including capacitive humidity sensors, resistive humidity sensors, thermal conductivity sensors), position and displacement sensors (including linear variable differential transformers (LVDT), rotary encoders, potentiometric sensors, proximity sensors), speed and motion sensors (including tachometers, encoders, doppler sensors), load and force sensors (including load cells, piezoelectric force sensors, torque sensors), pH and conductivity sensors (including pH sensors, conductivity sensors), light and optical sensors (including photoelectric sensors, fiber optic sensors, laser sensors), magnetic sensors (including Hall Effect sensors, magnetostrictive sensors), radiation sensors (including Geiger-Muller tubes, scintillation detectors), environmental sensors (including weather sensors, air quality sensors, water quality sensors), acoustic and ultrasonic sensors (including acoustic emission sensors, ultrasonic sensors), any other sensor, and combinations thereof. In some embodiments, the sensors 222 may include an operating state of a piece of equipment. The operating state may include powered up, powered down, energy level, open, closed, any other operating state, and combinations thereof.

When the user requests a digital twin, or an update to the digital twin, the digital twin generator 234 may identify the relevant models and retrieve the most recent or most relevant sensor data or physical measurements. The digital twin generator 234 may update the historical sensor data 244 in the models 236 with the new physical measurements. This may result in an up-to-date evergreen digital twin 202. As discussed herein, the evergreen digital twin 202 may include any type of twin, such as a process twin 224, an asset twin 226, a flow twin 228, a visual twin 230, any other digital twin, and combinations thereof. The evergreen digital twin 202 may generate an output, including a status of the physical asset based on the bound parameters 238 and the one or more static parameters 240.

The digital twin manager 232 may update the evergreen digital twin 202 periodically, episodically, or a combination of periodically and episodically. The digital twin manager 232 may update the evergreen digital twin 202 periodically based on an update period. In some embodiments, the update period may be in a range having an upper value, a lower value, or upper and lower values including any of once per second, once per minute, once per hour, once per day, once per week, once per month, once per year, or any value therebetween. For example, the update period may be greater than once per second. In another example, the update period may be less than once per year. In yet other examples, the update period may be any value in a range between once per second and once per year. In some embodiments, it may be critical that the update period is between once per hour and once per day to facilitate regular updating and monitoring of the evergreen digital twin 202 by the operator. In some embodiments, the digital twin manager 232 may update the evergreen digital twin 202 periodically based on a measurement frequency of one or more of the sensors 222. In some embodiments, the measurement frequency may be as low as 100 Hz. In some embodiments, the measurement frequency may be monthly or yearly. In some embodiments, the measurement frequency may be flexible, able to be configured on demand at the individual equipment level, across equipment types, or even across full facilities. The digital twin manager 232 may employ not only fixed time frames for periodic running, but also trigger on events (e.g., temp or pressure spikes above/below thresholds) and also on more complex logic that takes into consideration the overall risk associated to an equipment (e.g., risk score might incorporate sensor data, maintenance data, physics and data models) that would cause a re-run of the twin.

The digital twin manager 232 may update the 202 episodically based on a trigger event. The trigger event may be any trigger event, such as a request by the user, a threshold change in conditions, scheduled maintenance, unscheduled maintenance, any other trigger event, and combinations thereof.

The digital twin manager 232 may include a digital twin service orchestrator 246. The digital twin service orchestrator 246 may perform one or more services using the evergreen digital twin 202. For example, the digital twin service orchestrator 246 may perform one or services including optimizations 248, what-if scenarios 250, case studies 252, forecasting 254, any other service, and combinations thereof. To perform a service, the digital twin service orchestrator 246 may adjust one or more of the bound parameters 238 and identify the output. The digital twin service orchestrator 246 may identify the changes to the output based on the changes to the bound parameters 238. In this manner, the services performed by the digital twin service orchestrator 246 may be used to identify the impact of changes to the physical asset without making those changes. When the operator identifies a change to the physical asset that is desirable, the operator may implement the changes as simulated by the digital twin service orchestrator 246. The digital twin manager 232 may cause the sensors 222 to measure additional physical measurements and update the evergreen digital twin 202.

The optimization 248 services may target one or more optimization objectives. For example, the optimization 248 services may target an objective function, or combination of objective functions (with weight factors) by minimization using manipulated variables (inputs to the bound parameters 238) and considering constraints calculated values (e.g., values that cannot exceed thresholds). The digital twin service orchestrator 246 may run one or more optimization 248 services and save the results for the user.

The what-if scenarios 250 may include workflows, including user experience workflows, where the user may define, configure, save, and run different scenarios, using the evergreen digital twin 202 as a base. In some embodiments, the user may define input variables to be modified, including one or more of the bound parameters 238, from the evergreen digital twin 202. The what-if scenarios 250 may return a list of the impacted variables and results from the evergreen digital twin 202. The user may identify the evergreen digital twin 202 that the what-if scenarios 250 are compared to. The what-if scenarios 250 may triggered or operated in any manner, including periodically, or based on a certain scenario period, episodically, or based on a particular event, or manually, or based on a user triggering the what-if scenario. This may allow the operator to identify how changes to the bound parameters 238 may impact the physical asset.

In some embodiments, the digital twin service orchestrator 246 may implement case studies 252. The case studies 252 may include changes to multiple variables, such as multiple variables of the bound parameters 238. The case studies 252 may be run on a range of values. The case studies 252 may return a list of results based on the changed variables. As discussed herein, the case studies 252 may be run periodically, episodically, or manually.

In some embodiments, the digital twin service orchestrator 246 may implement forecasting 254 of time-dependent operations. The forecasting 254 may implement time as an input, or periods of time as an input. This may result in recommendations to change operations.

The digital twin manager 232 may further include a visualization manager 256. The visualization manager 256 may prepare a visualization of one or more of the evergreen digital twin 202. For example, the visualization manager 256 may prepare a process flow diagram (PFD), a two-dimensional rendering of the physical asset, a three-dimensional rendering of the physical asset, graphs, charts, tables, or other visual elements representative of the physical asset.

As discussed herein, the digital twin service orchestrator 246 may allow the user to analyze how adjusting the bound parameters 238 impact the physical asset without changing the actual parameters of the physical asset.

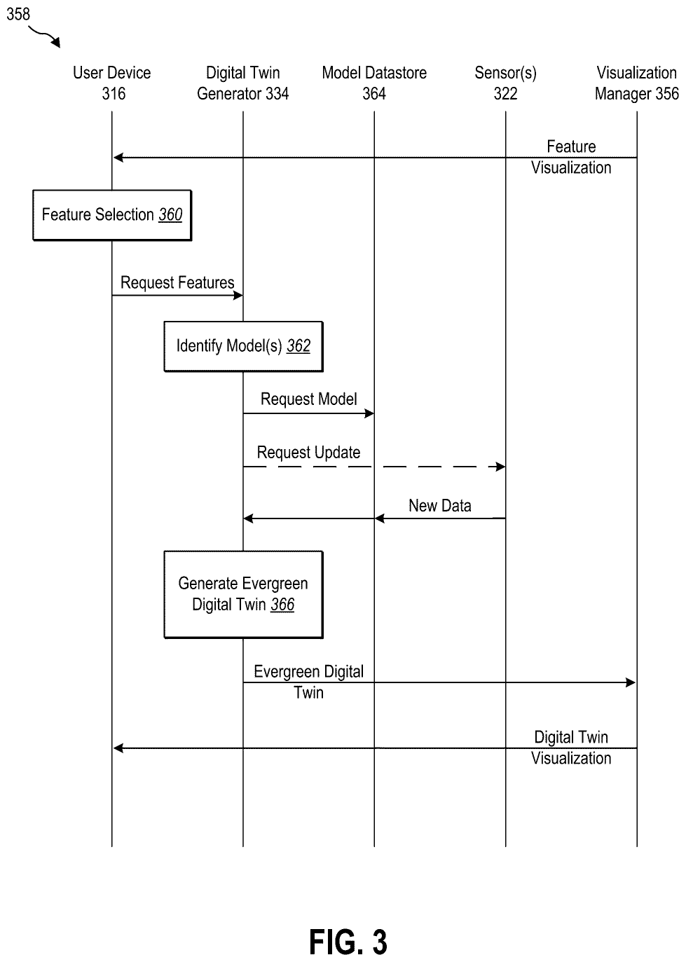

FIG. 3 is a string diagram 358 of the generation of an evergreen digital twin, according to at least one embodiment of the present disclosure. A user may, at a user device 316, receive a feature visualization from a visualization manager 356. From the feature visualization, the user may select 360 one or more features. For example, the user may desire to generate a digital twin of a facet of a physical asset. The physical asset may include one or more features, which may be represented on a graphical user interface (GUI). The user may select the desired features, and request the features from a digital twin manager.

A digital twin generator 334 may receive the request for a digital twin. The digital twin generator 334 may identify 362 one or more models that may be used to generate the digital twin. The digital twin generator 334 may request the models from a model datastore 364. The digital twin generator 334 may further request an update to the status of the physical asset from one or more sensors 322. The sensors 322 may provide physical measurements to the model datastore 364 and/or the digital twin generator 334, and the model datastore 364 may provide the models to the digital twin generator 334.

The digital twin generator 334 may, upon receiving the models and/or the updated data, generate 366 the evergreen digital twin. The digital twin generator 334 may provide the evergreen digital twin to the visualization manager 356. The visualization manager 356 may provide a visualization of the evergreen visual twin, and provide the visualization to the user device 316. In this manner, the digital twin generator may generate a digital twin representative of current conditions of the physical asset.

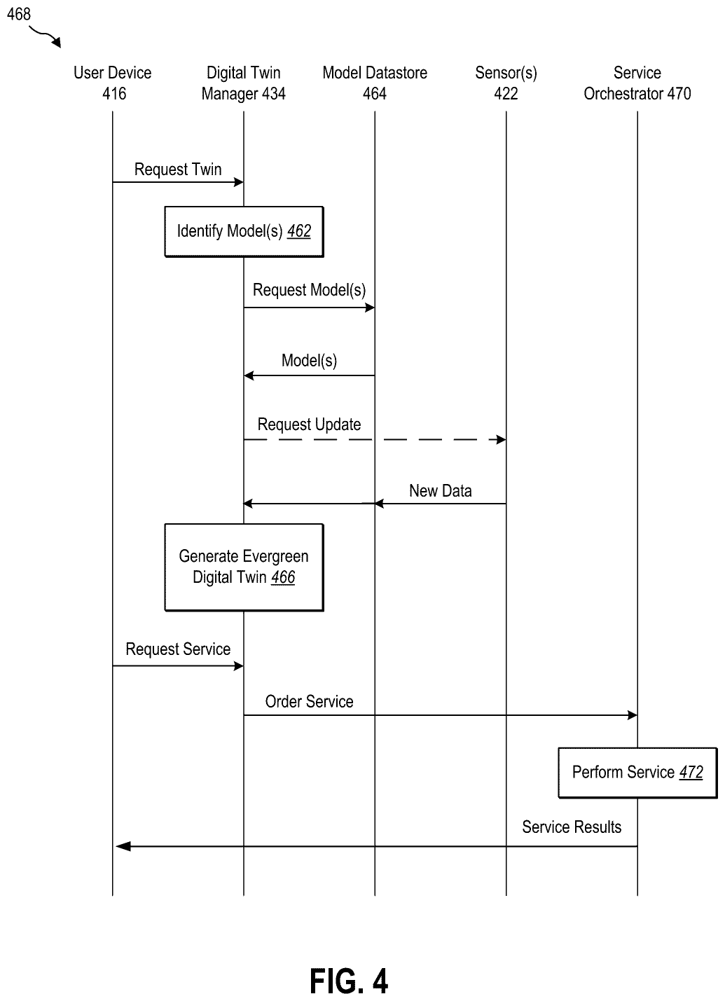

FIG. 4 is a string diagram 468 of the generation of an evergreen digital twin, according to at least one embodiment of the present disclosure. A user may desire to generate a digital twin of a facet of a physical asset. The physical asset may include one or more features, which may be represented on a graphical user interface (GUI). The user may select the desired features, and, from a user device 416, request the digital twin from a digital twin manager. A digital twin generator 434 may receive the request for a digital twin. The digital twin generator 434 may identify 462 one or more models that may be used to generate the digital twin. The digital twin generator 434 may request the models from a model datastore 464. The digital twin generator 434 may further request an update to the status of the physical asset from one or more sensors 422. The sensors 422 may provide physical measurements to the model datastore 464 and/or the digital twin generator 434, and the model datastore 464 may provide the models to the digital twin generator 434. The digital twin generator 434 may, upon receiving the models and/or the updated data, generate 466 the evergreen digital twin.

In accordance with at least one embodiment of the present disclosure, the user may, from the user device 416, request a service. The digital twin generator 434 may receive the request for the service and order the service from a service orchestrator 470. As discussed in further detail herein, the service orchestrator 470 may perform 472 the service. The service orchestrator 470 may then send the results of the service to the user device 416.

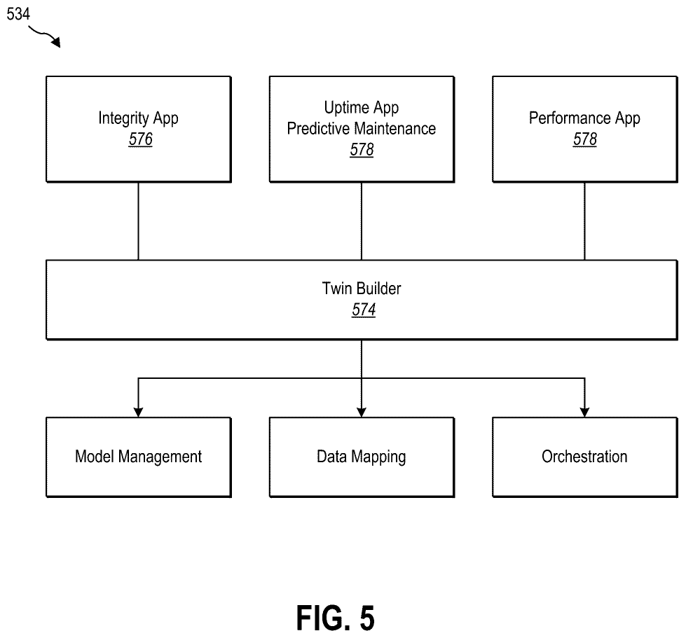

FIG. 5 is a schematic illustration of a digital twin generator 534, according to at least one embodiment of the present disclosure. The digital twin generator 534 may include a twin builder 574. The twin builder may be in communication with one or more apps, including an integrity app 576, an uptime app 578, and a performance app 580. The integrity app 576 may improve or maintain the integrity of the pipeline, proactively operate against regulatory systems, manage physical site visits, mange data collection from various instruments, and so forth.

The uptime app 578 may provide online monitoring of facilities to detect anomalies and predict future faults, provide prognostic machine-learning based models to advise on operational issues, and improve the remaining operational live of a particular asset. For example, the uptime app 578 may be in communication with the sensors at the physical asset and identify anomalies based on the sensor data. This may result in increased asset uptime and help to reduce or prevent unplanned shutdowns. The performance app 580 may provide insights from digital process digital twins aimed at improving the operation of a facility by providing optimization solutions targeting various objectives.

As discussed herein, the twin builder 574 may perform one or more actions. For example, the twin builder 574 may perform model management, including maintaining up-to-date and stable versions of the models underlying the digital twins. The twin builder 574 may further include data mapping systems, which may map data from sensors and operating states to the bound parameters of the models. The twin builder 574 may further include orchestration systems, which may perform orchestration services, as discussed herein. These systems may facilitate improved digital twin generation and monitoring.

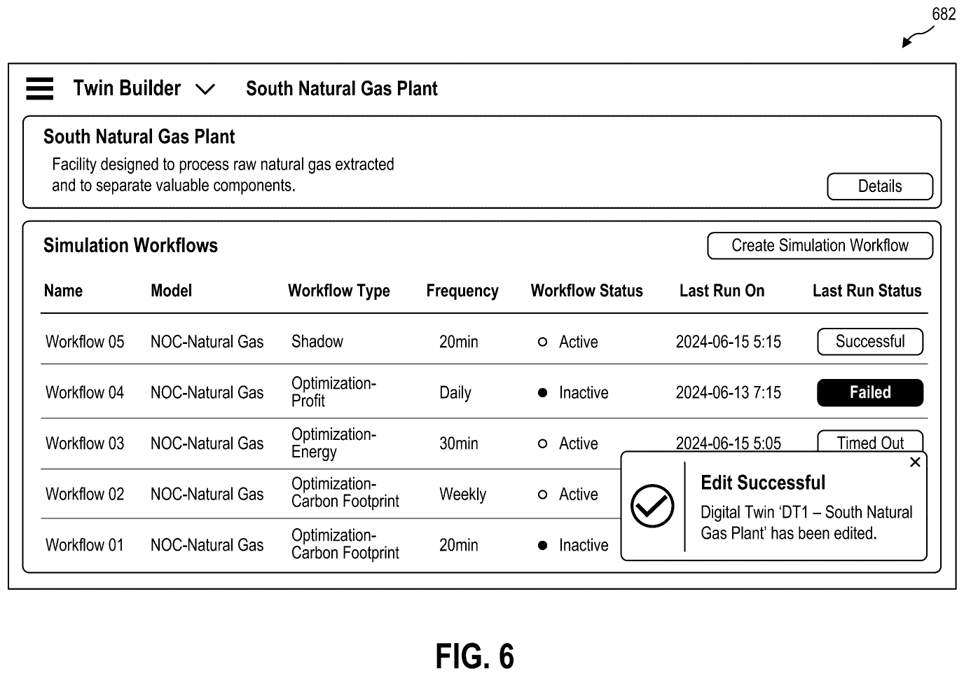

FIG. 6 is a representation of a GUI of a digital twin builder 682, according to at least one embodiment of the present disclosure. The GUI may include information regarding the digital twin, including the simulation workflows, the model associated with the workflow, the workflow type, the workflow frequency, the workflow status, the date of the last run, and the last run status. One or more elements of the GUI of the twin builder 682 may include selectable or interactive icons. A user may select the icons to arrange, rearrange, generate an arrangement, toggle, add, delete, filter, or otherwise receive or provide additional information for the digital twin. For example, the user may select on the failed last run status of the simulation workflow 4. The user may identify relationships between the icons, including relationships between at least two of the icons. This may generate a new window that may provide information regarding why the simulation workflow failed.

In the specific, non-limiting example provided in FIG. 6, the twin builder 682 has included five different simulation workflows having different workflow types and/or frequencies. The digital twin is for a “Natural Gas Plant.” As an example, Simulation Workflow 1 is a representation of an optimization workflow to optimize for the facilities carbon footprint. This workflow is implemented every twenty minutes, and at the time of the capture of this screen, the Simulation Workflow 1 was inactive.

Simulation Workflow 2 is a representation of an optimization workflow to optimize for the facilities carbon footprint. The frequency of this workflow is weekly, indicating that this workflow focuses on larger trends. The workflow status is indicated as active at the time of capture. The workflow is identified as successful.

Simulation Workflow 3 is a representation of an optimization workflow optimized for energy consumption. This workflow is performed every 30 minutes, and was active at the time of capture. The workflow was previously not completed due to a timeout.

Simulation Workflow 4 is a representation of an optimization workflow optimizing for facility profit. The simulation is run daily, and was inactive at the time of capture. The last run of this simulation failed.

Simulation Workflow 5 is a representation of a shadow workflow, or a workflow that is representative of the natural gas plant without making any changes. The workflow is run every 20 minutes, active at the time of capture, and the last run was successful.

By analyzing the outputs of the workflows, the operator may identify new operating conditions for the natural gas plant and/or identify areas of concern in the physical asset.

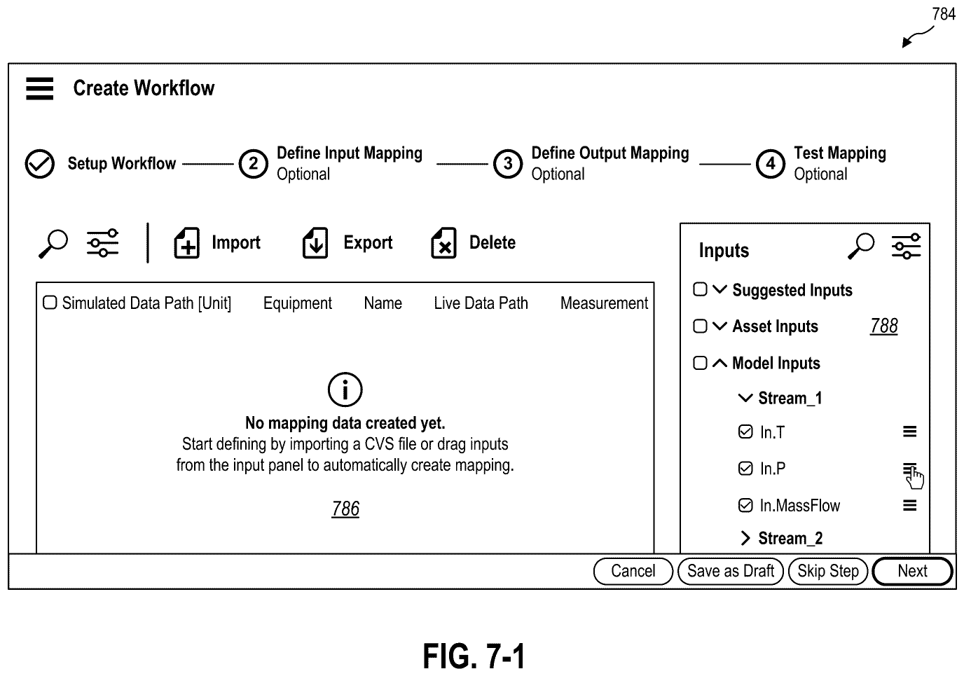

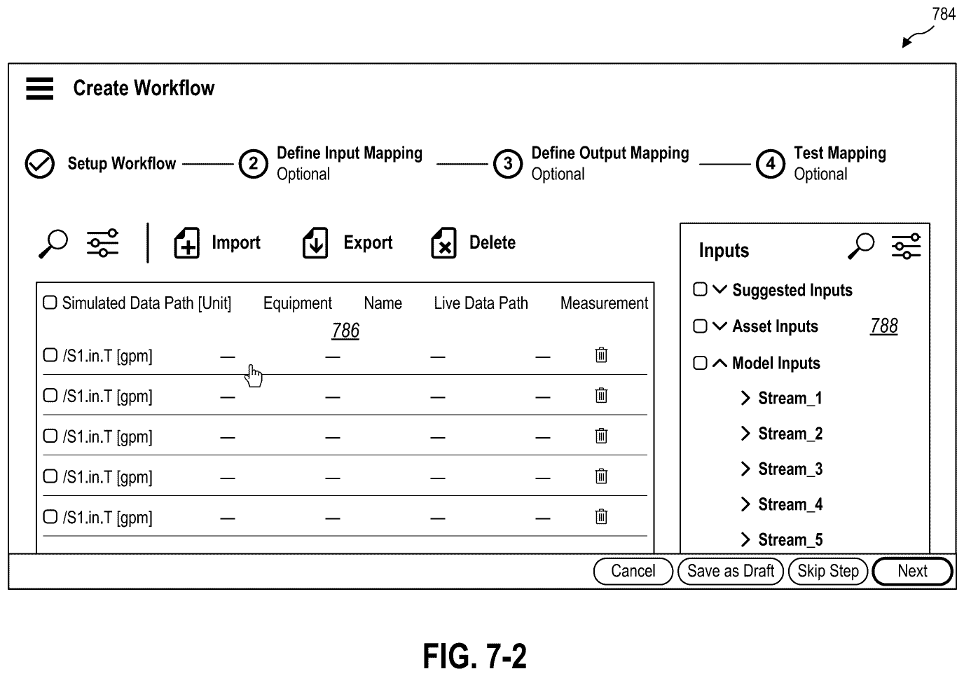

FIG. 7-1 is a representation of a GUI of a data binding manager 784, according to at least one embodiment of the present disclosure. The data binding manager 784 may include an equipment section 786 to input equipment and other processes that may receive sensor data as input. An input section 788 may include the available inputs for a particular physical asset. In FIG. 7-1, the user may set up the workflow for a particular physical asset.

In FIG. 7-2, the user may map or bind specific inputs (e.g., physical measurements) to particular elements of the workflow. As discussed herein, mapping or binding these inputs may occur manually and/or using the assistance of one or more artificial intelligence or machine learning models.

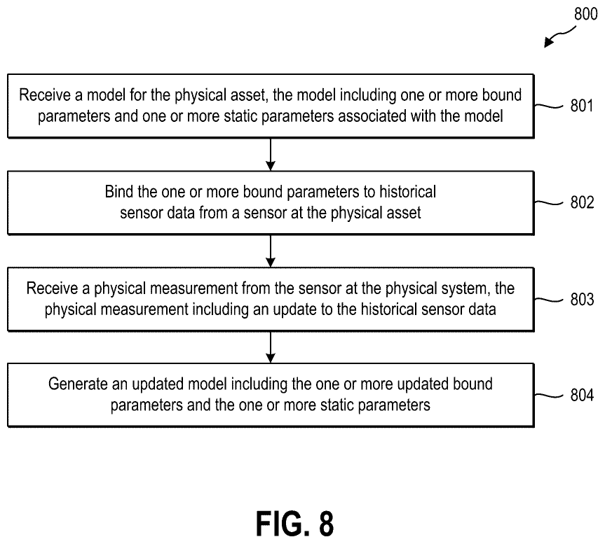

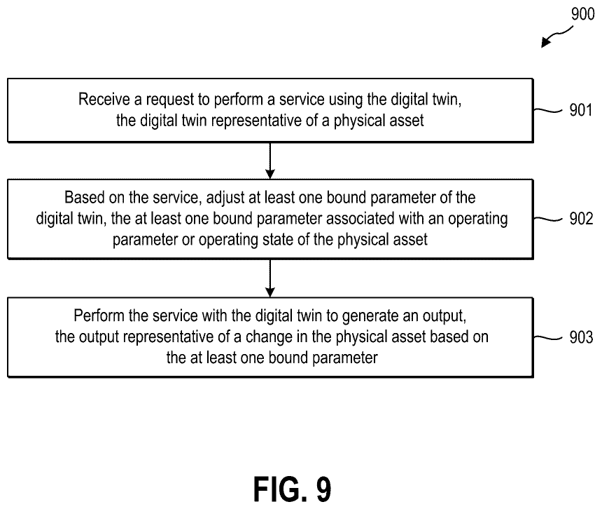

FIGS. 8 and 9, the corresponding text, and the examples provide a number of different methods, systems, devices, and computer-readable media of the digital twin generation system. In addition to the foregoing, one or more embodiments can also be described in terms of flowcharts comprising acts for accomplishing a particular result, as shown in FIGS. 8 and 9. FIGS. 8 and 9 may be performed with more or fewer acts. Further, the acts may be performed in differing orders. Additionally, the acts described herein may be repeated or performed in parallel with one another or parallel with different instances of the same or similar acts.

As mentioned, FIG. 8 illustrates a flowchart of a series of acts or a method 800 for generating a digital twin, according to at least one embodiment of the present disclosure. While FIG. 8 illustrates acts according to one embodiment, alternative embodiments may omit, add to, reorder, and/or modify any of the acts shown in FIG. 8. The acts of FIG. 8 can be performed as part of a method. Alternatively, a computer-readable medium can comprise instructions that, when executed by one or more processors, cause a computing device to perform the acts of FIG. 8. In some embodiments, a system can perform the acts of FIG. 8.

A digital twin generator may receive a model for a physical system at 801. The model may include one or more bound parameters and one or more static parameters associated with and/or used to build the model. The digital twin generator may bind the one or more bound parameters to historical sensor data from a sensor at the physical asset at 802. The digital twin generator may receive a physical measurement from the sensor at the physical system at 803. The physical measurement may include an update to the historical sensor data. For example, the physical measurement may be measured using the same sensor as the historical sensor data. In some examples, the physical measurement may be measured using a sensor measuring the same parameter as the historical sensor data. In some embodiments, the physical measurement may be measured using a different sensor at the same location as the historical sensor data. In some embodiments, the physical measurements may replace the historical sensor data, or the historical sensor data may be replaced with the physical measurements.

The digital twin generator may generate an updated model including the one or more updated bound parameters and the one or more static parameters at 804. The updated model may be an evergreen digital twin based on the update to the historical sensor data from the sensor data. In this manner, the digital twin generator may generate a digital twin and maintain the relevance and accuracy of the digital twin with respect to the physical system.

As discussed herein, a service orchestrator may perform one or more services using the evergreen digital twin. For example, the service orchestrator may, using the updated model (e.g., the evergreen digital twin), simulate the physical asset to generate a simulation result. The operator may then adjust at least one operating parameter of the physical asset based on the simulation result. This may improve the operation of the physical asset.

In some embodiments, simulating the physical asset may include adjusting the one or more bound parameters of the model or the updated model. In some embodiments, simulating the physical asset may include adjusting a plurality of bound parameters, or multiple bound parameters. In some embodiments, simulating the physical asset may include adjusting one of the bound parameters.

As mentioned, FIG. 9 illustrates a flowchart of a series of acts or a method 900 for generating a digital twin, according to at least one embodiment of the present disclosure. While FIG. 9 illustrates acts according to one embodiment, alternative embodiments may omit, add to, reorder, and/or modify any of the acts shown in FIG. 9. The acts of FIG. 9 can be performed as part of a method. Alternatively, a computer-readable medium can comprise instructions that, when executed by one or more processors, cause a computing device to perform the acts of FIG. 9. In some embodiments, a system can perform the acts of FIG. 9.

A service orchestrator may receive a request to perform a service using a digital twin representative of a physical asset at 901. Based on the requested service, the service orchestrator may adjust at least one bound parameter of the digital twin at 902. The bound parameter may be associated with an operating parameter and/or operating state of the physical asset. The service orchestrator may perform the service with the digital twin to generate an output at 903. The output is representative of a change in the physical asset based on the at least one bound parameter.

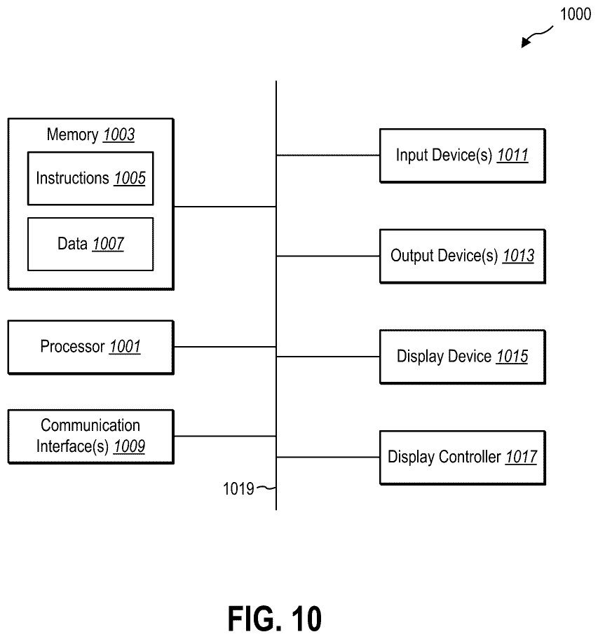

FIG. 10 illustrates certain components that may be included within a computer system 1000. One or more computer systems 1000 may be used to implement the various devices, components, and systems described herein.

The computer system 1000 includes a processor 1001. The processor 1001 may be a general-purpose single or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 1001 may be referred to as a central processing unit (CPU). Although just a single processor 1001 is shown in the computer system 1000 of FIG. 10, in an alternative configuration, a combination of processors (e.g., an ARM and DSP) could be used.

The computer system 1000 also includes memory 1003 in electronic communication with the processor 1001. The memory 1003 may be any electronic component capable of storing electronic information. For example, the memory 1003 may be embodied as random access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth, including combinations thereof.

Instructions 1005 and data 1007 may be stored in the memory 1003. The instructions 1005 may be executable by the processor 1001 to cause the processor 1001 to implement some or all of the functionality disclosed herein. Executing the instructions 1005 may involve the use of the data 1007 that is stored in the memory 1003. Any of the various examples of modules and components described herein may be implemented, partially or wholly, as instructions 1005 stored in memory 1003 and executed by the processor 1001. Any of the various examples of data described herein may be among the data 1007 that is stored in memory 1003 and used during execution of the instructions 1005 by the processor 1001.

A computer system 1000 may also include one or more communication interfaces 1009 for communicating with other electronic devices. The communication interface(s) 1009 may be based on wired communication technology, wireless communication technology, or both. Some examples of communication interfaces 1009 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

A computer system 1000 may also include one or more input devices 1011 and one or more output devices 1013. Some examples of input devices 1011 include a keyboard, mouse, microphone, remote control device, button, joystick, trackball, touchpad, and lightpen. Some examples of output devices 1013 include a speaker and a printer. One specific type of output device that is typically included in a computer system 1000 is a display device 1015. Display devices 1015 used with embodiments disclosed herein may utilize any suitable image projection technology, such as liquid crystal display (LCD), light-emitting diode (LED), gas plasma, electroluminescence, or the like. A display controller 1017 may also be provided, for converting data 1007 stored in the memory 1003 into text, graphics, and/or moving images (as appropriate) shown on the display device 1015.

The various components of the computer system 1000 may be coupled together by one or more buses, which may include a power bus, a control signal bus, a status signal bus, a data bus, etc. For the sake of clarity, the various buses are illustrated in FIG. 10 as a bus system 1019.

### INDUSTRIAL APPLICABILITY

In accordance with at least one embodiment of the present disclosure, a digital twin generator generates digital twins using a set of modular processes. The modular processes may include various models, simulations, visualizations, equipment, sensors, datasets, databases, other functions and/or data, or combinations thereof. The digital twin generator may include a graphical user interface (GUI) that may allow a user to visualize the modular processes for the digital twin. The digital twin generator may receive process information (e.g., through the GUI and/or directly). The process information may include at least one of sensor information, equipment information, facility information, hierarchical information, structural information, or power generation. The digital twin generator may receive workflow information for the digital twin (e.g., through the GUI and/or directly). The workflow information may include a twin type, the twin type may include at least one of a process twin or an asset twin. The digital twin generator may apply a twin builder model to the workflow information and/or the process information. The twin builder model may build the digital twin from this information.

In some embodiments, the user may rearrange the modular physical assets or processes and/or identify relationships between them. The digital twin generator may include an interface to the various physical assets or processes. This may allow the modular physical assets or processes to receive input from other processes and/or to generate outputs usable by the other processes. This may allow the digital twin generator, in at least one embodiment, to generate digital twins that easily and/or readily incorporate the input from various different systems. In some embodiments, the resulting digital twins are more representative of real-world conditions. In some embodiments, the resulting digital twins are faster, easier, and cheaper to generate. In some embodiments, the resulting digital twins are generated using fewer processing resources.

In some embodiments, the digital twin generator includes a series of tools and/or workflows that enable a deployment user and/or team to manage models through a repository system and employ them to generate and maintain digital twins in an intuitive and efficient manner. The digital twin generator may serve as a one-stop-shop configuration tool for the different simulation workflows used by a particular system (process, asset, flow twins, visual twins). This may reduce the deployment and maintenance time of the digital twin by simplifying and automating tasks such as data exploration, assisted data binding, orchestration of simulation runs, results management through various displays, and management of the evergreen models for further troubleshooting of the system and potentially facility solution data model creation or re-use.

In accordance with at least one embodiment of the present disclosure, the digital twin generator may include services that may facilitate a user creating, managing orchestrating, visualizing, and combinations thereof, a digital twin. Such digital twins may include one or more of process twins, asset twins, flow twins, any other type of digital twin, and combinations thereof. A process twin may be based on process models for a facility, such as a physics model, surrogate models, and hybrid models. An asset twin may be based on data models and hybrid models for equipment, including physics models. A flow twin may include an integration of flow assurance models, physicals, and hybrid driven models.

In some embodiments, the digital twin generator includes various services and engines that may facilitate the generation of digital twins. For example, the digital twin generator may include a model management engine. The model management engine may perform one or more operations including the storage and retrieval of the models used to generate the digital twin, versioning and version management of the models used to generate the digital twin, user entitlement, basic metadata, such as author, comments, changes, engine version, and compatibility, a visual display of model process flow diagrams (PFDs) when navigating models and model versions, and a comparison of changes between model versions.

In some embodiments, the digital twin generator includes a workflow orchestration manager. The workflow orchestration manager may facilitate the triggering of a particular workflow or model execution. The workflow orchestration manager may include an interface that may allow the various workflows and models to receive and/or send information to each other. In some embodiments, the workflow orchestration manager includes a visual component to allow the user to configure the digital twin without generating customized programming code. In some embodiments, the workflow orchestration manager includes a scheduling and manual start/stop of workflows. In some embodiments, the workflow orchestration manager includes event based triggers that implement various workflows or models based on particular triggers. In some embodiments, the workflow orchestration manager may orchestrate the implementation of, integration of, and communication between various different workflows and models.

In some embodiments, the digital twin generator includes simulation service engine. The simulation service engine may control the access and maintenance of services used for the execution of models and simulations. The simulation service engine may control the implementation of physics driven models. Physics driven models may include any physics-based models, including process models, flow assurance models, drilling models, geological models, steady state simulation models, dynamic simulation models, any other models, and combinations thereof. The simulation service engine may control the implementation of data models. The simulation service engine may control the implementation of custom models, including the execution of code, equations, and correlations.

In some embodiments, the digital twin generator includes a visualization manager. The visualization manager may include workflows to allow the user to visualize the visual twin. For example, the visualization manager may include a GUI that may allow the user to visualize the various modular processes used to generate the visualization. In some examples, the visualization manager may include a GUI that may allow the user to visualize the outputs of the digital twin. In some examples, the visualization manager may include a GUI that may allow the user to visualize the source of data. In some embodiments, the visualization manager may include a GUI that may include virtual sensors, or sensors that are generated by the digital twins. In some embodiments, the visualization manager may include a GUI that may include a visual status of the various models and workflows in the digital twin.

The digital twin generator may include a data layer that integrates and contextualizes data from various sources. For example, the data layer may integrate data from structured sources. Structured data may include any type of structured data, such as numerical data, tabular data, spreadsheet or csv data, any other structured data, and combinations thereof. In some examples, the data layer may integrate data from unstructured sources. Unstructured data may include any type of unstructured data, such as written data, image data, verbal data, text, reports, any other unstructured data, and combinations thereof. Utilizing a data layer may allow the digital twin generator to utilize any type of data from various sources, including internet of things (IoT) devices, sensors, enterprise systems, operation management systems, crew management systems, any other source, and combinations thereof.

As discussed herein, the various processes utilized by the digital twin generator may be modular. A modular approach may allow the digital twin generator to be used as a flexible source to generate different digital twins. For example, modular processes may allow the user to mix-and-match the processes to be used when generating a particular digital twin. In this manner, and in accordance with at least one embodiment of the present disclosure, the digital twin generator may allow the user to generate flexible digital twins that are applicable to a variety of processes and situations.

The digital twin generator may include multiple workflows. The workflows may allow the user to capture unique behaviors of a particular system. Such workflows may include one or more of shadow workflows, optimization workflows, asset twin/data workflows, scenario workflows, calibration workflows, any other workflow, and combinations thereof. A shadow workflow may be based on a physics and/or data driven simulation model. Optimization workflows may include minimization or maximization of an objective function (e.g., profit, throughput, energy, emissions) based on a set of manipulated variables and constraints. The optimization workflows are performed using a model (e.g., a simulation or a data model), updating the inputs, and then performing various optimization algorithms to find the minimum or maximum based on current conditions. Asset twin/data workflows may include proactive monitoring and prognostics of equipment and systems including condition monitoring, anomaly detection, failure prediction, and remaining useful life. Scenario workflows may include manual workflows for “what if” scenarios that allow a user to identify changes to a system, using the latest available model (e.g., latest version, updated with latest data) and analyze possible results and outcomes. Calibration workflows may assess the overall health of a particular model used in a digital twin. The system may advise whether a model may not perform as expected (e.g., that the model is out of calibration) and may attempt an automated calibration of the model. The calibration workflow may keep track of the changes made for user review.

The digital twin generator may include reusable workflows. Reusable workflows may be workflows that are usable for various different digital twins. As discussed herein, conventional workflows may be custom-made and/or customized for a particular digital twin, resulting in little to no re-usability without specialized modification. The re-usable workflows discussed herein may be applicable to various workflows, thereby increasing the versatility of the digital twin generator.

The digital twin generator may facilitate data binding between various processes in a digital twin. Data binding may be one of the most time-consuming tasks in the generation of a particular digital twin. Data binding may involve the creation of a map between sensor data and the simulation model. Further, maintenance of a binding map may be time-consuming. The digital twin generator may include a binding assistant. The binding assistant may include the contextualization of the data layer and the pre-defined and re-usable data models to suggest a particular pairing. The binding assistant may monitor the versioning and changing of particular models for binding a digital twin. In this manner, and in accordance with at least one embodiment of the present disclosure, the binding assistant may improve the accuracy of the binding process and/or reduce the risk of issues and maintenance of the digital twin throughout the life of the digital twin.

In accordance with at least one embodiment of the present disclosure, the digital twin generator may include a solution data model. The solution data model may be a structure representative of a particular asset or facility as a set of interconnected and hierarchical sub-equipment or plant. The solution data model may include a GUI that allows the user to generate a digital twin from pre-defined assets, select processes, reconfigure the assets, and connect to data sources and/or simulation or data models. This may improve the configuration of the digital twin.

As discussed herein, the digital twin generator may include an orchestration manager. The orchestration manager may orchestrate the implementation, communication, and timing of the various models and workflows of a digital twin. The orchestration manager may allow the user to connect data and different models that allows for the desired flow of information.

The embodiments of the digital twin generator have been primarily described with reference to physical assets used in oil and gas environments; the digital twin generators described herein may be used in applications other than physical assets in oil and gas environments. In other embodiments, digital twin generators according to the present disclosure may be used outside an oil and gas environment used for the exploration or production of natural resources. For instance, digital twin generators of the present disclosure may be used in manufacturing systems. Accordingly, the terms “oil and gas,” “drilling” and the like should not be interpreted to limit tools, systems, assemblies, or methods of the present disclosure to any particular industry, field, or environment.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method for generating an evergreen digital twin of a physical asset, the method comprising:
receiving a model for the physical asset, the model including one or more bound parameters and one or more static parameters associated with the model;
binding the one or more bound parameters to historical sensor data from a sensor at the physical asset;
receiving a physical measurement from the sensor at the physical asset, the physical measurement including an update to the historical sensor data; and
generating an updated model including the one or more updated bound parameters and the one or more static parameters.

2. The method of claim 1, further comprising:
using the updated model, simulating the physical asset to generate a simulation result; and
adjusting at least one operating parameter of the physical asset based on the simulation result.

3. The method of claim 2, wherein simulating the physical asset includes adjusting the one or more bound parameters of the model.

4. The method of claim 3, wherein the one or more bound parameters includes a plurality of bound parameters, and wherein adjusting the plurality of bound parameters includes adjusting each of the plurality of bound parameters.

5. The method of claim 3, wherein the one or more bound parameters includes a plurality of bound parameters, and wherein adjusting the plurality of bound parameters includes adjusting one of the plurality of bound parameters across a range of values.

6. The method of claim 1, wherein updating the historical sensor data with the physical measurement includes updating the historical sensor data periodically with an update frequency.

7. The method of claim 6, wherein the update frequency is between once per day and once per hour.

8. The method of claim 1, wherein updating the historical sensor data with the physical measurement includes updating the historical sensor data episodically based on a trigger event.

9. The method of claim 8, wherein the trigger event includes a request to simulate the physical asset using the evergreen digital twin.

10. The method of claim 1, wherein updating the historical sensor data includes replacing the historical sensor data with the physical measurement.

11. The method of claim 10, further comprising storing an instance of the model based on the historical sensor data.

12. A method for implementing a digital twin, the method comprising:
receiving a request to perform a service using the digital twin, the digital twin representative of a physical asset;
based on the service, adjusting at least one bound parameter of the digital twin, the at least one bound parameter associated with an operating parameter or operating state of the physical asset; and
performing the service with the digital twin to generate an output, the output representative of a change in the physical asset based on the at least one bound parameter.

13. The method of claim 12, further comprising:
receiving a physical measurement from a sensor; and
before performing the service, updating the digital twin based on the physical measurement to generate an evergreen digital twin.

14. The method of claim 13, wherein the physical measurement is bound to the at least one bound parameter.

15. The method of claim 13, wherein updating the digital twin includes updating the digital twin based on the request.

16. The method of claim 12, wherein the service includes at least one of an optimization, a what-if scenario, a case study, or a forecast.

17. The method of claim 12, further comprising, based on the output, adjusting the operating parameter or the operating state of the physical asset.

18. A system, comprising:
a processor and memory, the memory including instructions that cause the processor to:
receive a model for a physical asset, the model including one or more bound parameters and one or more static parameters associated with the model;
bind the one or more bound parameters to historical sensor data from a sensor at the physical asset;
receive a physical measurement from the sensor at the physical asset, the physical measurement including an update to the historical sensor data; and
generate an updated model including the one or more updated bound parameters and the one or more static parameters.

19. The system of claim 18, wherein the instructions further cause the processor to:
using the updated model, simulate the physical asset to generate a simulation result; and
adjust at least one operating parameter of the physical asset based on the simulation result.

20. The system of claim 19, wherein simulating the physical asset includes adjusting the one or more bound parameters of the model.
